(19) United States
(12) Patent Application Publication
(10) Pub. No.: US 2012/0088327 A1
(43) Pub. Date: Apr. 12, 2012

(54) Methods of Soldering to High Efficiency Thin Film Solar Panels

(75) Inventors: Adam Brand, Palo Alto, CA (US); Fei Wang, Fremont, CA (US); Inchu Chang, Cupertino, CA (US); Kuo-Wei Liu, San Jose, CA (US); Markus Kress, Muehlheim am Main (DE); Axel Straub, Ingelheim (DE)

(73) Assignee: Applied Materials, Inc., Santa Clara, CA (US)

(21) Appl. No.: 13/191,123

(22) Filed: Jul. 26, 2011

Related U.S. Application Data
(60) Provisional application No. 61/368,048, filed on Jul. 27, 2010.

(51) Int. Cl. H01L 31/18

(52) U.S. Cl. 438/72; 257/E31.124; 257/E31.127

(57) ABSTRACT

Methods for forming a thin film solar cell are provided. In one aspect, a thin film solar cell is formed by providing a back contact comprising a reflective material and an interface metal, applying a solder paste slurry that include a paste flux and metal particles to the interface metal and soldering at least one buss wire to back contact.

### CROSS-REFERENCE TO RELATED APPLICATIONS

This application claims the benefit under 35 U.S.C. §119(e) of U.S. Provisional Application No. 61/368,048, filed Jul. 27, 2010.

### BACKGROUND

Embodiments of the present invention generally relate manufacturing of thin film solar cells and modules. More specifically, embodiments of the invention relate to methods of soldering buss wires to the back contact of thin film solar cells.

In thin film solar or photovoltaic cells, also reflection of initially-unabsorbed light from the back contact allows for additional absorption in the cell to increase device current, and conversion efficiency. The use of zinc oxide (ZnO) with a silver stack layer for tandem junction solar cells yields the highest bottom cell current for physical vapor deposition (PVD) produced back contact thin film stacks.

However, silver has low adhesion to aluminum doped zinc oxide (AZO), a commonly used back contact conducting layer. Therefore, to reduce delamination at the interface of the AZO and silver layers, an active metal layer is often used. This active metal layer, also called an “adhesive metal layer”, is generally a thin layer including chromium, titanium, tantalum or other active metals. The purpose of this metal layer is to improve interface strength (i.e., adhesion) between the AZO layer and the silver layer. Due to the introduction of this adhesive metal layer between the AZO and silver layers, some light is absorbed and, therefore, the reflection from the silver layer is reduced. This reduced reflection causes a decrease in the current produced by the photovoltaic cell.

Without the adhesive metal layer, the adhesion of the silver layer to the AZO layer is, technically speaking, sufficient to provide good device performance with the highest current and best conversion efficiency. The biggest problem occurs during the soldering process employed to connect a buss wire to the back contact. During this soldering, the back contact is subjected to high temperature (greater than about 220° C.) and solder flux material, a potentially corrosive chemical, which causes delamination between the AZO and silver interface.

Delamination is not solely due to poor adhesion (interface strength) between AZO and the silver layers, but due to other factors as well. The factors that affect the delamination include, in no particular order: (1) interface strength (adhesion between the AZO layer and the silver layer; (2) high temperatures applied to the back contact during soldering causing film cracks along grain boundaries; (3) the corrosive flux used during soldering; (4) a combination of high temperature during soldering and the corrosive flux reacting with the silver and causing delamination at the AZO interface; and (5) film stress mismatch between films in the back contact stack causes sever delamination and flux penetration (and corrosion) during soldering due to thermal stress, resulting in delamination at the AZO—silver interface.

The current soldering process for manufacturing thin film solar cells uses high temperatures to solder buss wires. The high temperatures can result in delamination and solder marks that are visible on the front surface of the solar cell. Additionally, the high temperatures shorten the lifetime of thermodes, or similar devices, used to solder the buss wires.

Another concern with soldering of thin film solar cells is that typical back contact materials used in thin film applications, for example, silver, can be reactive. For example, the back contact often reacts with soldering flux. The need to maintain the reflective or optical properties of the back contact, while limiting reactions with the back contact materials, presents another challenge. Accordingly, there is a need for improved soldering processes for attaching buss wires to a back contact for use in thin film solar cells.

### SUMMARY OF THE INVENTION

One or more aspects of the present invention pertain to a method for forming a thin film solar cell module. In one or more embodiments, the method for forming a thin film solar cell module includes forming a thin film back contact comprising a reflective metal and an interface metal, applying a solder paste slurry comprising a paste flux and metal particles on the interface metal and soldering at least one side bus wire to the thin film back contact. The solder paste slurry may be applied on the interface metal by using a screen printing process, an auger dispense process or a pressure dispense process. The buss wire of one or more embodiments may be soldered to the flux at a melting point temperature in the range from about 130° C. to about 230° C. In another variant, the soldering paste may have a melting point and soldering at least one buss wire to the back contact includes heating the soldering paste to the melting point to melt the solder. Melting the solder in one or more embodiments of the method causes the flux to reduce and produces an antioxidative action.

The methods described herein may also include disposing a thermally conductive buffer layer on the silver layer to provide strain relief to the back contact during soldering. In one or more embodiments, the method may also include disposing a thermally conductive buffer layer on the silver layer to provide strain relief to the back contact during soldering.

The buffer layer described herein may include a metal selected from one or more of Al, Cu and W. In one or more embodiments, the buffer layer has a thickness sufficient to disperse the heat applied to the back contact. The buffer layer may also have a thickness in the range from about 50 Angstroms to about 300 Angstroms. The interface layer described herein may include a metal selected from one or more of Ni, V, Ti, Au, and Pt.

In one or more embodiments, the buss wire utilized by the methods described may include a metal different from the reflective metal of the back contact. In one or more specific embodiments, the buss wire comprises Cu, Al, Cu-plated with Ni, Sn, SnAg and combinations thereof.

In one or more variants of the present invention, the solder paste slurry utilized in the methods disclosed herein includes acid rosin, solvents and viscosity modifiers. The paste flux utilized in one or more embodiments may be characterized as a no clean paste flux. The solder paste slurry of one or more variants may include one or more of SnPb, SnAg, SnAgCu, SnAgCuNi, SnAu, SnCu and SnBi. The metal particles utilized in one or more embodiments may include one or more of SnPb, SnAg, SnAgCu, SnAgCuNi, SnAu, SnCu, and SnBi. In another variant, the metal particles may include alloy particles selected from one or more of Sn/0.58Bi, Sn-3.8Ag-0.7Cu, Sn-0.7Cu, Sn-2Ag-0.8Cu-0.5Sb, Sn-3.5Ag.

The foregoing has outlined rather broadly certain features and technical advantages of the present invention. It should be appreciated by those skilled in the art that the specific embodiments disclosed may be readily utilized as a basis for modifying or designing other structures or processes within the scope present invention. It should also be realized by those skilled in the art that such equivalent constructions do not depart from the spirit and scope of the invention as set forth in the appended claims.

### BRIEF DESCRIPTION OF THE DRAWINGS

FIG. 1A is a side cross-sectional view of a thin film solar cell module according to one or more embodiment of the invention;

FIG. 1B is a side cross-sectional view of a thin film solar cell module according to one or more embodiment of the invention;

FIG. 2 is a plan view of a composite solar cell module according to one or more embodiment of the invention;

FIG. 3 shows a cross-sectional view of a photovoltaic module along Section 3-3 of FIG. 2; and

FIG. 4 shows a graph illustrating the adhesive strength of a samples made in accordance with embodiments of the present invention and samples utilizing an adhesive metal layer.

### DETAILED DESCRIPTION

Embodiments of the invention generally provide methods for manufacturing a thin film solar cell including providing a back contact, applying a paste flux containing metal particles to the back contact, and soldering at least one buss wire to the flux. According to one or more embodiments, thin film solar cells made according to the disclosed methods in the absence of an adhesive metal layer exhibit comparable interface strength between the AZO layer and the silver layer compared to thin film solar cells made according to conventional thin film solar cells which utilize the adhesive metal layer. An advantage of manufacturing solar cells according to one or more embodiments is that the absence of the adhesive metal layer results in less absorption in the solar cell and greater reflection from the silver layer, ultimately resulting in greater current production by the thin film solar cell.

As used herein, the phrase “adhesive metal layer” refers to a thin layer including chromium, titanium, tantalum or other active metals between the silver layer and the AZO layer of a thin film photovoltaic cell. As used herein, a thin film photovoltaic cell refers to a photovoltaic cell having deposited layers of silicon less than 10 microns in thickness, and is made by depositing layers using a physical vapor deposition process.

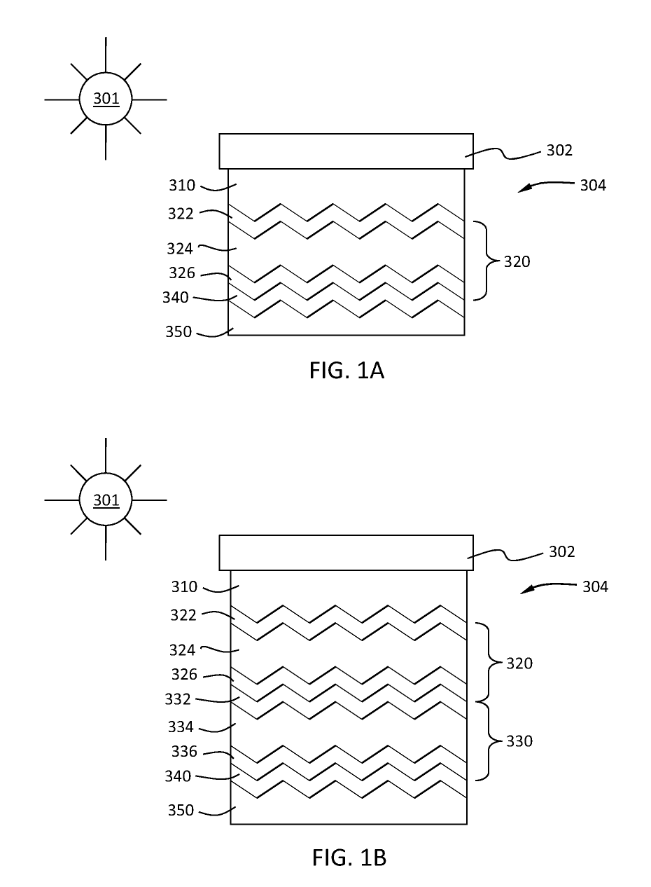

FIG. 1A shows a single junction amorphous silicon solar cell 304 is oriented toward a light source or solar radiation 301. The solar cell 304 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 304 further comprises a first transparent conducting oxide (TCO) layer 310 (e.g., zinc oxide (ZnO), tin oxide (SnO) or aluminum zinc oxide (AZO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 1A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to, a material selected from the group consisting of Al, Ag, Ti, Cr, Au, Cu, Pt, Ni, Mo, conductive carbon, alloys thereof, and combinations thereof.

FIG. 1B is a schematic diagram of an embodiment of a solar cell 304, which is a multi-junction solar cell that is oriented toward the light or solar radiation 301. The solar cell 304 comprises a substrate 302, such as a glass substrate, polymer substrate, metal substrate, or other suitable substrate, with thin films formed thereover. The solar cell 304 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340.

In the embodiment shown in FIG. 1B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, Ni, Mo, conductive carbon, alloys thereof, and combinations thereof.

As mentioned above, reflection of initially-unabsorbed light from the back contact allows for additional absorption in the cell to increase device current, and conversion efficiency. The use of zinc oxide (ZnO), typically AZO, with a silver stack layer for tandem junction solar cells yields the highest bottom cell current for physical vapor deposition (PVD)-produced back contact stacks. Thus, back contact layer 350 typically comprises several sublayers. A typical back contact layer 350 comprises a chromium (Cr) layer (which is sometimes referred to as the adhesion or adhesive metal layer) over the ZnO/AZO layer, a silver layer (sometimes referred as the reflective layer) over the Cr layer and an interface or passivation layer (typically NiV) over the silver layer. Each of these sublayers of the back contact layer 350 is not shown in the Figures.

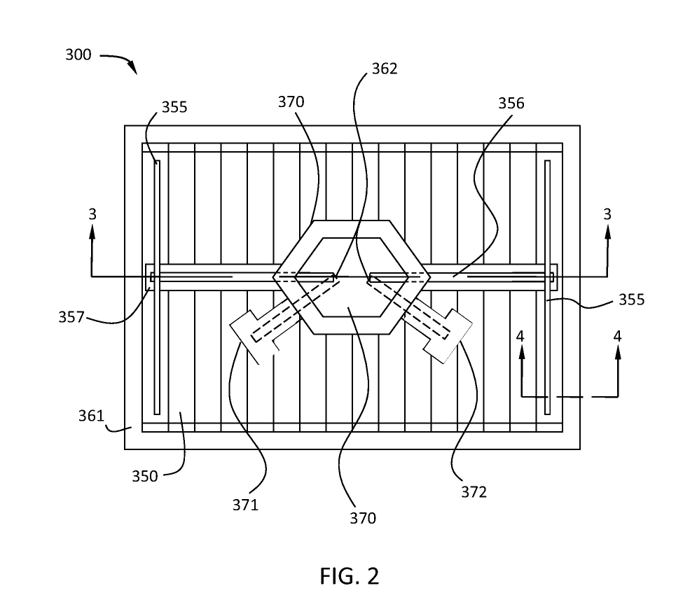

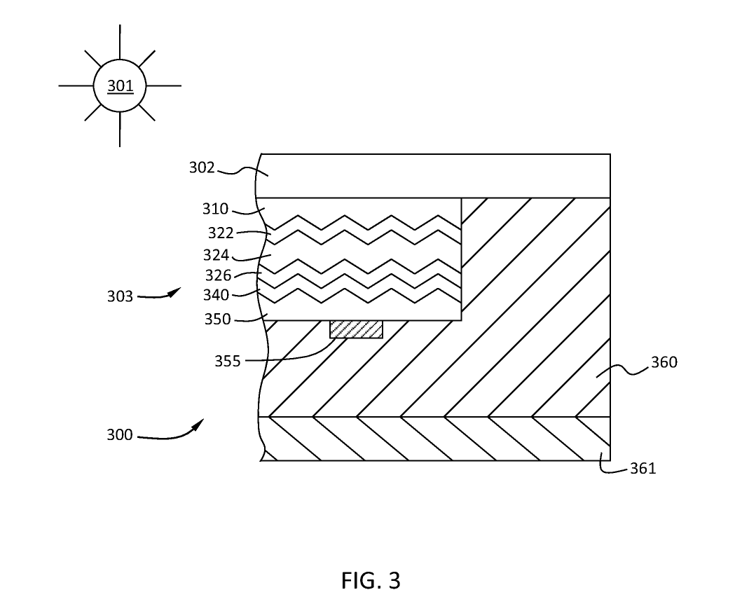

FIG. 2 is a plan view that schematically illustrates an example of the rear surface of a solar cell module 300 produced by the previously described procedure. FIG. 3 shows a side cross-sectional view of the thin-film solar cell module 300 of FIG. 2. While FIG. 3 illustrates the cross-section of a single junction cell similar to the configuration described in FIG. 1A, this is not intended to be limiting as to the scope of the invention described herein.

As shown in FIGS. 2-4, the solar cell module 300 may contain a substrate 302, the solar cell device elements (e.g., reference numerals 310, 322, 324, 326, 340 and 350), one or more internal electrical connections (e.g., side-buss 355, cross-buss 356), a layer of bonding material 360, a back glass substrate 361, and a junction box 370. The junction box 370 may generally contain two junction box terminals 371, 372 that are electrically connected to leads 362 of the solar cell module 300 through the side-buss 355 and the cross-buss 356, which are in electrical communication with the back contact layer 350 and active regions of the solar cell module 300. To avoid confusion relating to the actions specifically performed on the substrates 302 in the discussion above, a substrate 302 having one or more of the deposited layers (e.g., reference numerals 310, 322, 324, 326, 340 and 350) and/or one or more internal electrical connections (e.g., side-buss 355, cross-buss 356) disposed thereon is generally referred to as a device substrate 303. Similarly, a device substrate 303 that has been bonded to a back glass substrate 361 using a bonding material 360 is referred to as a composite solar cell module 300. An insulating material 357 is shown in FIG. 2 isolating the side-buss 355 from the cross-buss 356.

A first aspect of the present invention pertains to a method for manufacturing a thin film solar cell and joining solar cells into a solar cell module. In one embodiment, a paste flux and a soldering material are selected for compatibility with the materials that make up the back contact layer 350. One or more embodiments of the method include forming a back contact comprising a reflective metal (for example, silver) and an interface metal (for example, NiV, Ti, Au, or Pt), applying a solder paste slurry to the interface metal, and soldering at least one buss wire to back contact. In accordance with one or more embodiments, the solder paste slurry includes a paste flux and metal particles. The paste flux contains acid rosin, solvents and viscosity modifiers, and has a higher viscosity than liquid fluxes.

As is understood in the art, the interface layer may be used as the top or outer layer of the back contact stack to provide corrosion resistance and a workable bus attach surface. The buss wire to be attached to the back contact according to one or more embodiments may be formed from materials that include Cu, Al, and/or Cu-plated with Ni, Sn, and/or SnAg.

In one or more embodiments, the solder paste slurry, which will be described in more detail herein, may incorporate a solder material selected from one or more of SnPb, SnAg, SnAgCu, SnAgCuNi, SnAu, SnCu, SnBi and combinations thereof. The solder material may be provided as a coating on a buss wire. In one or more embodiments, the solder may be provided in a paste with other components.

In one or more embodiments, the solder paste may include one or more organic solvents, one or more viscosity modifiers and/or one or more surfactants. Examples of suitable organic solvents include benzene, toluene, and α-terineol. Examples of viscosity modifiers include glycerol, polyethylene glycol and a hydrogenated castor oil. Examples of surfactants include an anime halogenated hydroacid salt and diphenyl guanidine HBr.

One or more embodiments according to the present invention may also utilize a solder paste that includes metal particles. The solder paste and metal particles are provided in a slurry. Suitable metal particles include SnPb, SnAg, SnAgCu, SnAgCuNi, SnAu, SnCu, SnBi and combinations thereof. The metal particles may include a single type of metal or may include more than one type of metal. Suitable alloys known in the art include Sn/0.58Bi, Sn-3.8Ag-0.7Cu, Sn-0.7Cu, Sn-2Ag-0.8Cu-0.5Sb and Sn-3.5Ag, though others known in the art may also be utilized. In such embodiments, it is believed that the slurry prevents the flux from reacting aggressively with the reflecting metal during the soldering process.

The flux utilized in one or more embodiments prevents oxidation reactions by becoming strongly reducing at elevated temperatures, thus preventing the formation of metal oxides. The flux also acts as a wetting agent in the soldering process by reducing the surface tension of the molten solder. In one or more embodiments, the method may utilize a flux that may be characterized as a “no-clean” flux or a flux that does not leave a reside or leaves only a benign residue after the soldering process.

In one or more embodiments which utilize a solder paste slurry including metal particles, the solder paste slurry is formed by dispersing the metal particles in a paste flux. The paste flux may be prepared by mixing rosin with selected organic solvent, viscosity modifiers and surfactants.

In one or more embodiments, the solder paste includes rosins, and may include lead, tin, silver, bismuth, antimony, indium, copper and combinations thereof. Suitable solder pastes may also incorporate surfactants and viscosity modifiers. The solder paste may also include alloy particles, which may be provided in the paste as spherical and uniformly sized particles. The particle size of the alloys contained within the solder paste may have a particle size in the range from about 5 microns to about 75 microns. In one or more specific embodiments, the particle size may be in the range from about 25 microns to about 45 microns. The solder paste may have a metal load of up to 90% or may have a metal load of more than 90%. Solder pastes having a viscosity in the range from about 140 Kcps to about 1,000 Kcps may also be utilized in the embodiments described herein. In one or more specific embodiments, suitable solder pastes have a viscosity in the range from about 700 Kcps to 900 Kcps. In one or more specific embodiments, suitable solder pastes may have a viscosity in the range from about 700 Kcps to about 1,000 Kcps when used in printing applications and a viscosity of about 450 to 800 Kcps when utilized in dispensing applications.

Examples of suitable solder paste are available under the tradenames Amtech SynTECH-LF and Amtech SynTECH, which is available from Amtech, Inc. of Brandford, Conn. Other suitable solder pastes are available from Kester, Inc. of Itasca, Ill. under the tradenames NXGI and EnviroMark™ 907 and from Metallic Resources, Inc. of Twinsburg, Ohio under the tradename MetaPaste™ NC-500. Suitable solder pastes are also available from Solder Chemistry of Landshut, Germany under the tradenames BLF03 and BLF04 and Inidum Corp. of Utica, N.Y. under the tradename INDALLOY with Indium 5.8LS. In specific embodiments, the paste flux is a no clean flux, which means that low conductivity residues from the flux remain on the solar cell after the soldering process is completed. In use, the solder paste slurry is applied to the surface of the back contact. In one or more embodiments, the solder paste slurry is applied by screen printing, auger dispense, pressure dispense and other methods known in the art. The buss wire is placed on the surface of the back contact. The solder paste slurry is then heated to its melting point, which may be in the range from about 138° C. to about 700° C. The heat can be applied through a hot solder tip, a thermode, direct ohmic heating or other energy transfer methods. The heat source utilized may operate at a more specific temperature range, for example, in the range from about 250° C. to about 450° C. As the solder melts, the flux is reduces and produces an antioxidative action. When the melted solder is solidified, the mounting end of each lead is connected to the back contact via a solder layer left from the solder paste. According to embodiments of the invention, an advantage of using the paste flux in the soldering of thin film solar cells is that the amount of reactive material to the thin film layer is better controlled than with conventional processes.

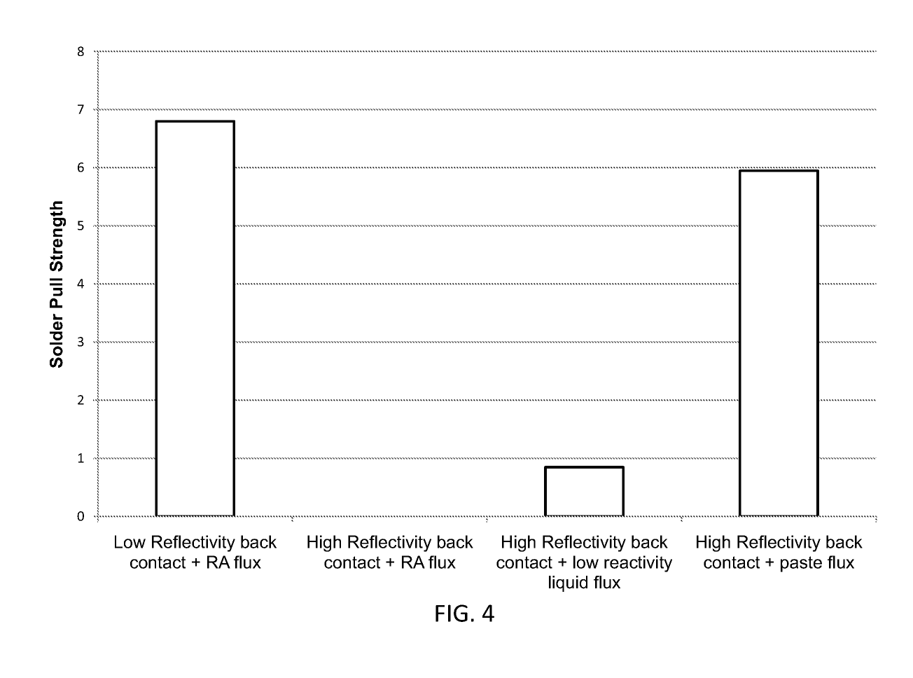

Several samples were soldered using a conventional process in which a metal adhesive layer of thickness between 10 A and 50 A was formed between an AZO film and Ag film. Conventionally, a liquid soldering flux of type RA (Rosin Activated) or RMA (Rosin Mildly Activated) are used. The liquid flux may have a viscosity in the range of 1-100 cps. The results of the testing are shown in FIG. 4 and indicate that the samples made in accordance with embodiments of the present invention utilizing a solder paste slurry containing a paste flux and metal particles exhibited comparable adhesive strength between the AZO layer and silver layer of the back contact in the absence of an adhesive metal layer when compared with samples made using RA flux and including the adhesive layer. Thus, thin film solar cells can be manufactured exhibiting acceptable adhesive strength to prevent delamination between the silver an AZO layers of the back contact and exhibit increased reflection from the silver layer and increased current produced by the photovoltaic cell compared with samples that include the metal adhesive layer between the AZO and silver layers of the back contact. The sample utilizing a solder paste slurry containing a paste flux and metal particles also exhibited higher pull strength than samples using a high reflectivity back contact and either an RA flux or a low reactivity liquid flux.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A method of forming a thin film solar cell module comprising:
forming a thin film back contact comprising a reflective metal and an interface metal;
applying a solder paste slurry comprising a paste flux and metal particles on the interface metal; and
soldering at least one side buss wire to the thin film back contact, the buss wire comprising a metal different from the reflective metal of the back contact.

2. The method of claim 1, wherein the solder paste slurry comprises acid rosin, solvents and viscosity modifiers.

3. The method of claim 2, wherein the buss wire comprises Cu, Al, Cu-plated with Ni, Sn, SnAg and combinations thereof.

4. The method of claim 2, wherein the paste flux is a no clean paste flux.

5. The method of claim 2, wherein the solder paste is disposed on the interface metal by using one of a screen printing process, an auger dispense process or a pressure dispense process.

6. The method of claim 2, wherein the buss wire is soldered to the flux at a melting point temperature in the range from about 130° C. to about 230° C.

7. The method of claim 2, wherein the solder paste comprises one or more of SnPb, SnAg, SnAgCu, SnAgCuNi, SnAu, SnCu and SnBi.

8. The method of claim 2, wherein the metal particles are selected from one or more of SnPb, SnAg, SnAgCu, SnAgCuNi, SnAu, SnCu, and SnBi.

9. The method of claim 2, wherein the metal particles include alloy particles selected from one or more of Sn/0.58Bi, Sn-3.8Ag-0.7Cu, Sn-0.7Cu, Sn-2Ag-0.8Cu-0.5Sb, Sn-3.5Ag.

10. The method of claim 2, wherein the solder paste has a melting point and soldering the at least one buss wire to the back contact comprises heating the soldering paste to the melting point to melt the solder.

11. The method of claim 10, wherein melting the solder causes the flux to reduce and produces an antioxidative action.

12. The method of claim 2, further comprising disposing a thermally conductive buffer layer on the silver layer to provide strain relief to the back contact during soldering.

13. The method of claim 12, wherein the buffer layer comprises a metal selected from one or more of Al, Cu and W.

14. The method of claim 12, wherein the interface layer comprises a metal selected from one or more of Ni, V, Ti, Au, and Pt.

15. The method of claim 12, wherein the buffer layer has a thickness sufficient to disperse the heat applied to the back contact.

16. The method of claim 15, wherein the buffer layer has a thickness in the range from about 50 Angstroms to about 300 Angstroms.

17. The method of claim 2, wherein the buss wire comprises Cu, Al, Cu-plated with Ni, Sn, SnAg and combinations thereof.

18. A method of forming a thin film solar cell module, the method comprising:
applying a solder paste slurry to an interface metal, the solder paste slurry comprising a paste flux and metal particles; and
soldering at least one side buss wire to the thin film back contact, the buss wire comprising a metal different from the reflective metal of the back contact.

19. The method of claim 18, wherein the solder paste slurry comprises acid rosin, solvents and viscosity modifiers.

20. A method of forming a thin film solar cell module, the method comprising:
forming a thin film back contact comprising a reflective metal and an interface metal;
applying a solder paste slurry to the interface metal using one of a screen printing process, an auger dispense process or a pressure dispense process, the solder paste slurry comprising a paste flux and metal particles; and
soldering at least one side buss wire to the thin film back contact, the buss wire comprising a metal different from the reflective metal of the back contact.
